(19) United States
(12) Patent Application Publication
(10) Pub. No.: US 2022/0044911 A1
(43) Pub. Date: Feb. 10, 2022

(54) PLASMA TRANSPORT CHANNEL DEVICE AND COATING EQUIPMENT

(71) Applicant: ANHUI CHUNYUAN COATING TECHNOLOGY CO., LTD., Hefei (CN)

(72) Inventor: Xinfeng Zhang, Hefei (CN)

(21) Appl. No.: 17/507,871

(22) Filed: Oct. 22, 2021

Related U.S. Application Data
(63) Continuation of application No. PCT/CN2021/090880, filed on Apr. 29, 2021.

(30) Foreign Application Priority Data
Jul. 2, 2020 (CN) 202010627138.X

(51) Int. Cl. H01J 37/32

(52) U.S. Cl. CPC H01J 37/32357; H01J 2237/332; H01J 2237/002; H01J 37/32807

(57) ABSTRACT

The present invention relates to a plasma transport channel device and coating equipment, including a channel body. An A channel configured for a transport of a plasma is formed inside the channel body, two ends of the A channel constitute an A inlet and an A outlet, respectively, a cooling unit configured for cooling the channel body is arranged on or beside the channel body, and/or, an adsorption unit configured for adsorbing an impurity component in the plasma is arranged on an inner wall of the channel body. In the present invention, the channel body is cooled by the cooling unit arranged on or beside the channel body, so as to achieve the purpose of heat dissipation and temperature reduction of the channel body. The impurity component in the plasma is adsorbed by the adsorption unit arranged on the inner wall of the channel body, thereby improving the effect.

### CROSS REFERENCE TO RELATED APPLICATIONS

The present application is a Continuation Application of PCT Application No. PCT/CN2021/090880 filed on Apr. 29, 2021, which claims the benefit of Chinese Patent Application No. 202010627138.X filed on Jul. 2, 2020. All the above are hereby incorporated by reference in their entirety.

### FIELD OF THE INVENTION

The present invention relates to the field of vacuum coating equipment, and specifically to a plasma transport channel device and coating equipment.

### BACKGROUND OF THE INVENTION

Vacuum coating is to deposit plasmas generated by target materials on a product to be processed. Plasma generally contains about 10%-15% of charged ions and electrons, and the remaining of neutral particles, microscopic particles, etc. The charged ions have strong energy, and can be controlled by a magnetic field to increase ion capacity or change direction, which is extremely conducive to enhancing film adhesion and uniformity, reducing particles depositing on film, improving surface properties, and prolonging product service life. While the neutral particles cannot be controlled nor realize energy increase or direction change, thus less contributing to improving surface properties and extending product service life. All particles, ions, and impurities in the plasma will deposit on the surface of the product to be processed, which causes problems such as the existence of a large amount of relatively large particles on film, low film adhesion, the occurrence of defects, and uncontrollable uniformity. An ion transport channel device can be set to filter out the neutral particles and the microscopic particles, and only permit the transport of the charged ions and electrons, thereby enhancing film performance. However, the traditional ion transport channel device has many defects, for example, the temperature of transport channel will rise during the process of filtration of the neutral particles and the microscopic particles by the transport channel, which affects coating effect. Furthermore, the neutral particles and the microscopic particles depositing in the transport channel are inconvenient for cleaning. The transport channel may become narrow as the deposited neutral particles and microscopic particles increase, affecting smooth transport of the charged ions. Therefore, a further improvement is needed.

### SUMMARY OF INVENTION

The objective of the present invention is to provide a plasma transport channel device and coating equipment, which can cool a channel body and/or adsorb an impurity component in a plasma.

The present invention adopts the following technical solutions.

A plasma transport channel device includes a channel body, wherein an A channel configured for a transport of a plasma is formed inside the channel body, two ends of the A channel constitute an A inlet and an A outlet, respectively, a cooling unit configured for cooling the channel body is arranged on or beside the channel body, and/or, an adsorption unit configured for adsorbing an impurity component in the plasma is arranged on an inner wall of the channel body.

Preferably, the cooling unit is formed by an air-cooling device arranged outside the channel body.

Preferably, the cooling unit is formed by a cooling passage arranged on the channel body, and a cooling fluid is contained in the cooling passage.

Preferably, the cooling passage is arranged on an outer side wall of the channel body.

Preferably, the cooling passage is formed by an interlayer arranged on the channel body, and a cooling fluid inlet and a cooling fluid outlet are arranged on the cooling passage.

Preferably, the cooling passage is formed by a spiral tube arranged on the channel body, one end of the spiral tube is the cooling fluid inlet, and the other end of the spiral tube is the cooling fluid outlet.

Preferably, an adsorption unit is arranged along a length range of the channel body.

Preferably, the adsorption unit is formed by a plate or a block arranged on the inner wall of the channel body.

Preferably, the adsorption unit is formed by annular plates arranged on the inner wall of the channel body, a center line of each annular plate is consistent with a center line of the channel body, and the annular plates are arranged at intervals along a length direction of the channel body.

Preferably, the annular plate is in a trapezoid shape, and a distance between an inner ring side of the annular plate and the A inlet is smaller than a distance between an outer ring side and the A inlet.

Preferably, flanges are arranged at two ends of the channel body, respectively.

Preferably, a magnetic field device is arranged beside the channel body, and an intensity of a magnetic field applied by the magnetic field device is 0.01 T-0.98 T.

Preferably, the adsorption unit is detachably connected to the channel body.

Preferably, the channel body is made of stainless steel, oxygen-free copper, copper alloy, or aluminum alloy.

Preferably, a cross section of the spiral tube is circular, rectangular, or semicircular.

Preferably, the channel body is a bent tube or a folded tube.

Preferably, the A channel is a variable-diameter cavity-type channel.

Preferably, an included angle between a flow direction in the A inlet and a flow direction in the A outlet is 30°, 90°, 180°, or 270°.

Preferably, the channel body includes a straight tubular A channel body section and a straight tubular B channel body section located at two ends of the channel body, and the A channel body section and the B channel body section are connected by an arc-shaped C channel body section.

Preferably, a cross section of the A channel body section and a cross section of the B channel body section have the same size, and a cross section of the C channel body section and the cross section of the A channel body section have different sizes.

Preferably, a length of the A channel body section and a length of the B channel body section are different.

Preferably, a width of the interlayer forming the cooling passage is 1 mm-10 mm.

A coating equipment includes the above plasma transport channel device. The coating equipment is one or any combination of magnetron sputtering equipment, vacuum-arc equipment, chemical vapor deposition equipment and pure ion vacuum coating equipment.

The advantages achieved by the present invention are as follows.

In the plasma transport channel device provided by the present invention, the A channel is formed in the channel body, and the plasma is input from the A inlet at one end of the A channel, and output from the A outlet at the other end. In the process, the channel body is cooled by the cooling unit arranged on or beside the channel body, so as to achieve the purpose of heat dissipation and temperature reduction of the channel body. The impurity component in the plasma is adsorbed by the adsorption unit arranged on the inner wall of the channel body, thereby improving the effect.

Additionally, through using the above-mentioned plasma transport channel device, the coating equipment provided by the present invention can better filter impurities in the plasma and meanwhile cool the channel body in the working process, so as to ensure the plasma transport channel device continuously exerts a stable filtering effect, thus beneficial to improving the coating quality.

In addition to the objectives, features, and advantages described above, the present invention has other objectives, features, and advantages. Hereinafter, the present invention will be further described in detail with reference to the accompanying drawings.

### BRIEF DESCRIPTION OF THE DRAWINGS

The drawings constituting a part of the present application are used to provide a further understanding of the present invention, and the exemplary embodiments of the present invention and the descriptions thereof are used to explain the present invention, which do not constitute an improper limitation of the present invention. In the drawings:

FIG. 1 is a schematic diagram showing an assembly of a plasma transport channel device provided by an embodiment of the present application connected to an anode assembly, a vacuum chamber, and a scanning device, respectively, where an included angle between flow directions in the A inlet and the A outlet of the A channel is 30°;

FIG. 2 is a schematic diagram showing a structure of an annular plate provided by an embodiment of the present application;

FIG. 3 is a schematic diagram showing an assembly of a plasma transport channel device provided by another embodiment of the present application connected to an anode assembly, a vacuum chamber, and a scanning device, respectively, where an included angle between flow directions in the A inlet and the A outlet of the A channel is 90°;

FIG. 4 is a schematic diagram showing an assembly of a plasma transport channel device provided by yet another embodiment of the present application connected to an anode assembly, a vacuum chamber, and a scanning device, respectively, where an included angle between flow directions in the A inlet and the A outlet of the A channel is 180°;

FIG. 5 is a schematic diagram showing an assembly of a plasma transport channel device provided by a further embodiment of the present application connected to an anode assembly, a vacuum chamber, and a scanning device, respectively, where an included angle between flow directions in the A inlet and the A outlet of the A channel is 270°;

FIG. 6 is a schematic diagram showing a structure of a channel body provided by an embodiment of the present application, where an included angle between flow directions in the A inlet and the A outlet is 90°, L1>L2, and a cross section of spiral tube is circular;

FIG. 7 is a schematic diagram showing a structure of a channel body provided by an embodiment of the present application, where an included angle between flow directions in the A inlet and the A outlet is 90°, L1>L2, and a cross section of spiral tube is rectangular;

FIG. 8 is a schematic diagram showing a structure of a channel body provided by an embodiment of the present application, where an included angle between flow directions in the A inlet and the A outlet is 90°, L1>L2, and a cross section of spiral tube is elliptical;

FIG. 9 is a schematic diagram showing a structure of a channel body provided by an embodiment of the present application, where an included angle between flow directions in the A inlet and the A outlet is 90°, L1>L2, and a cooling passage is an interlayer structure;

FIG. 10 is a schematic diagram showing a structure of a channel body provided by an embodiment of the present application, where an included angle between flow directions in the A inlet and the A outlet is 90°, L1>L2, and a cooling unit is an air-cooling device;

FIG. 11 is a schematic diagram showing a structure of a channel body provided by an embodiment of the present application, where an included angle between flow directions in the A inlet and the A outlet is 90°, L1=L2, and a cross section of spiral tube is circular;

FIG. 12 is a schematic diagram showing a structure of a channel body provided by an embodiment of the present application, where an included angle between flow directions in the A inlet and the A outlet is 90°, L1<L2, and a cross section of spiral tube is circular;

FIG. 13 is a schematic diagram showing a structure of a channel body provided by an embodiment of the present application, where an included angle between flow directions in the A inlet and the A outlet is 30°, L1>L2, and a cross section of spiral tube is circular;

FIG. 14 is a schematic diagram showing a structure of a channel body provided by an embodiment of the present application, where an included angle between flow directions in the A inlet and the A outlet is 180°, L1>L2, and a cross section of spiral tube is circular;

FIG. 15 is a schematic diagram showing a structure of a channel body provided by an embodiment of the present application, where an included angle between flow directions in the A inlet and the A outlet is 270°, L1>L2, and a cross section of spiral tube is circular;

FIG. 16A is a detected image reflecting film performance of the surface of a workpiece, with a 1000-fold magnification, where the workpiece is treated by the coating equipment with the plasma transport channel device provided in the present application;

FIG. 16B is a detected image reflecting film performance of the surface of a workpiece, with a 1000-fold magnification, where the workpiece is treated by the coating equipment without the plasma transport channel device provided in the present application;

FIG. 17A is a detected image reflecting an adhesion between a film and a substrate product, where the workpiece is treated by the coating equipment with the plasma transport channel device provided in the present application;

FIG. 17B is a detected image reflecting an adhesion between a film and a substrate product, where the workpiece is treated by the coating equipment without the plasma transport channel device provided in the present application;

FIG. 18A is a detected image reflecting a film densification, where the workpiece is treated by the coating equipment with the plasma transport channel device provided in the present application;

FIG. 18B is a detected image reflecting a film densification, where the workpiece is treated by the coating equipment without the plasma transport channel device provided in the present application;

FIG. 19A is a detected image reflecting a film hardness, where the workpiece is treated by the coating equipment with the plasma transport channel device provided in the present application;

FIG. 19B is a detected image reflecting a film hardness, where the workpiece is treated by the coating equipment without the plasma transport channel device provided in the present application.

In the figures, reference numbers are illustrated as below:

00a-charged ion, 00b-impurity component, 00c-current, 00d-magnetic field, 100-channel body, 110-A channel, 120-A inlet, 130-A outlet, 140-A channel body section, 150-B channel body section, 160-C channel body section, 210-air-cooling device, 220-spiral tube, 230-interlayer, 410-annular plate, 411-inner ring side, 412-outer ring side, 500-flange, 600-magnetic field device, 700-insulating plate, 800-anode assembly, 900-plasma generator, 1000-vacuum chamber, 1100-scanning device.

### DETAILED DESCRIPTION OF ILLUSTRATED EMBODIMENTS

In order to make the purposes and advantages of the present application clearer, the present application is specifically illustrated below in conjunction with embodiments. It should be understood that the following contents are only used to describe one or more specific implementation modes of the present application, and do not strictly limit the scope of protection specifically claimed in the present application. In the case of no conflict, the embodiments and the limitations of the embodiments of the present application can be combined with each other.

### Embodiment 1

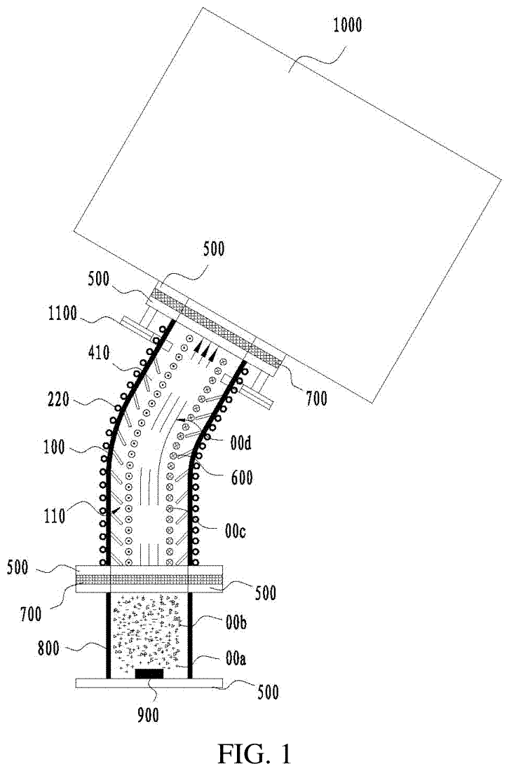

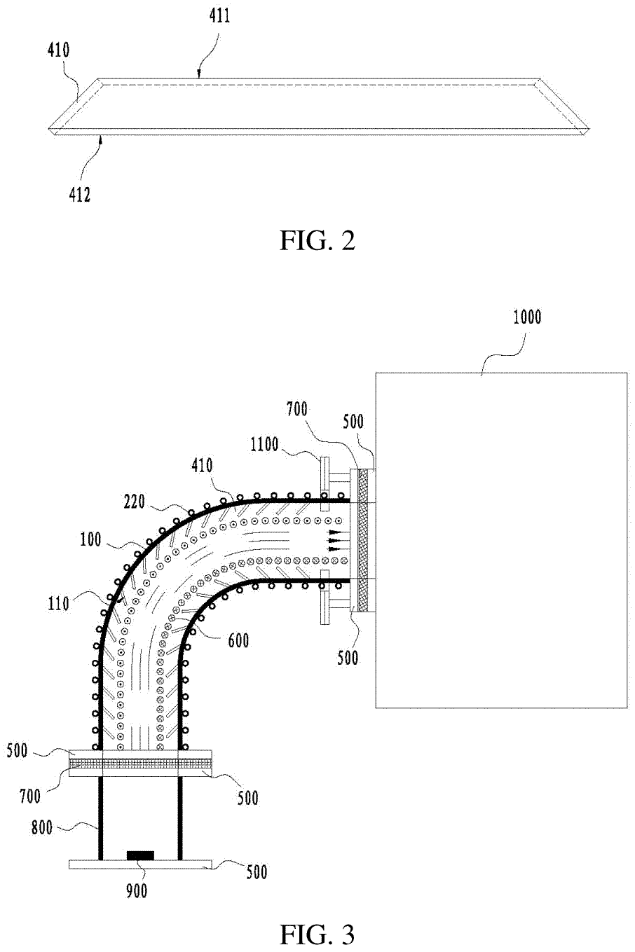

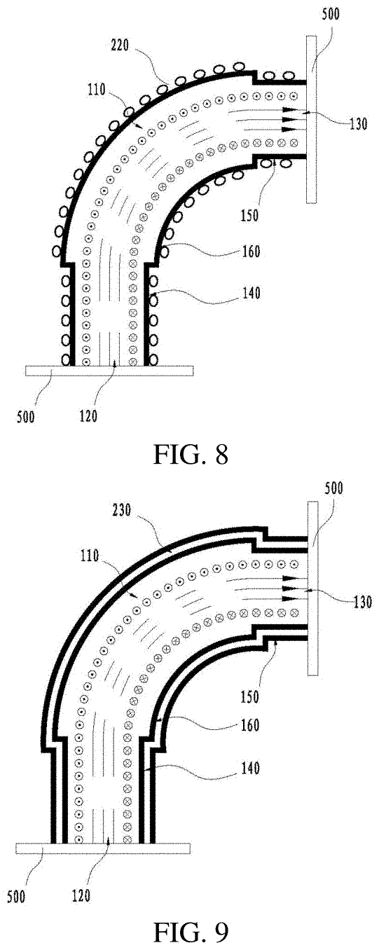

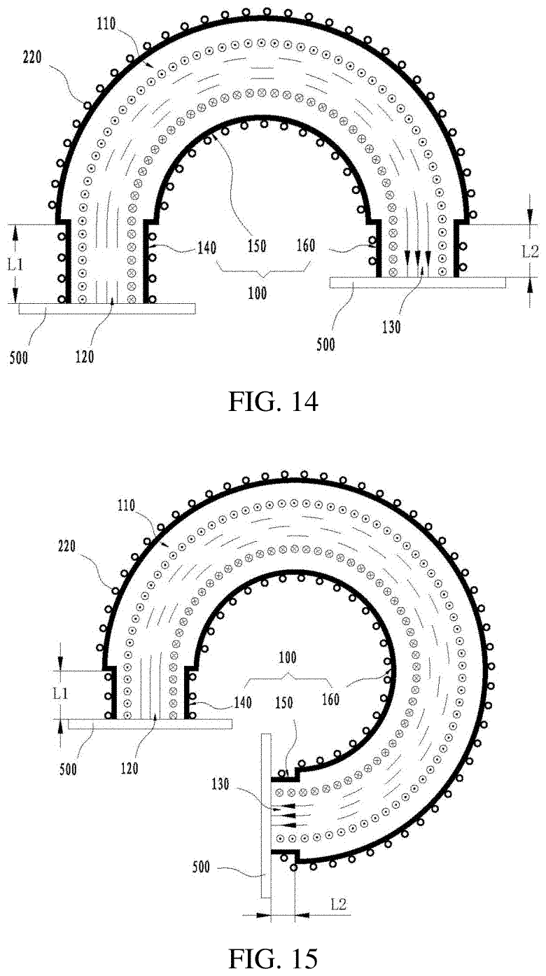

Referring to FIG. 1 to FIG. 15, the embodiment of the present application first provides a plasma transport channel device, which aims at solving the technical problems as follows: the temperature of a transport channel will be increased during the process of filtration of the impurity component 00b by the transport channel, thus affecting the coating effect; moreover, the impurity component 00b depositing in the transport channel is not convenient for cleaning, and the transport channel may become narrow as the deposited impurity component 00b increases, thereby affecting smooth transport of the charged ion 00a.

The embodiment of the present application provides an implementation as follows. The plasma transport channel device includes the channel body 100, and the A channel 110 configured for a transport of a plasma is formed inside the channel body 100. Two ends of the A channel 110 constitute the A inlet 120 and the A outlet 130, respectively. A cooling unit configured for cooling the channel body 100 is arranged on or beside the channel body 100, and/or, an adsorption unit configured for adsorbing the impurity component in the plasma is arranged on an inner wall of the channel body 100. The impurity component 00b includes neutral particles, impurities and microscopic particles.

In the plasma transport channel device provided by the embodiment of the present application, the A channel 110 is formed inside the channel body 100. The plasma is input from the A inlet 120 at one end of the A channel 110, and output from the A outlet 130 at the other end. During this process, the channel body 100 is cooled by the cooling unit arranged on or beside the channel body 100, thus achieving the purpose of heat dissipation and temperature reduction of the channel body 100. The impurity component 00b in the plasma is adsorbed by the adsorption unit arranged on the inner wall of the channel body 100, thereby improving the effect. When a cleaning operation is performed, only the adsorption unit needs to be cleaned. The above plasma transport channel device provided by the present application can filter out the impurity component, and only allows charged particles and electrons to pass through the channel, thereby enhancing film adhesion and uniformity, reducing particles depositing on film, improving surface properties, and greatly prolonging product service life.

Referring to FIG. 1 to FIG. 6, based on the above implementation, the present embodiment provides coating equipment, including the above-mentioned plasma transport channel device. The coating equipment is one or any combination of magnetron sputtering equipment, vacuum-arc equipment, chemical vapor deposition equipment and pure ion vacuum coating equipment.

Through using the above-mentioned plasma transport channel device, the coating equipment provided by the embodiment of the present application can concurrently filter the impurity component in the plasma and cool the channel body 100 in the working process, so as to ensure the plasma transport channel device continuously exerts a stable filtering effect, thus beneficial to improving a coating quality.

### Embodiment 2

Referring to FIG. 1 to FIG. 15, the embodiment of the present application also provides a plasma transport channel device, which aims to solve the technical problems as follows: the temperature of a transport channel is increased caused by bombardment of an impurity component and application of an electromagnetic field during the process of filtration of the impurity component by the transport channel, thereby affecting a coating effect.

The embodiment of the present application provides an implementation as follows. The plasma transport channel device includes the channel body 100, and the A channel 110 configured for a transport of a plasma is formed inside the channel body 100. Two ends of the A channel 110 constitute the A inlet 120 and the A outlet 130, respectively. A cooling unit configured for cooling the channel body 100 is arranged on or beside the channel body 100.

For the plasma transport channel device provided by the embodiment of the present application, the plasma enters from the A inlet 120 of the channel body 100, and exits from the A outlet 130. During the process of the plasma passing through the A channel 110, the temperature of the A channel 110 is increased. However, since the cooling unit is arranged on or beside the channel body 100, the channel body 100 can be cooled, thus achieving the purpose of heat dissipation and temperature control of the channel body 100.

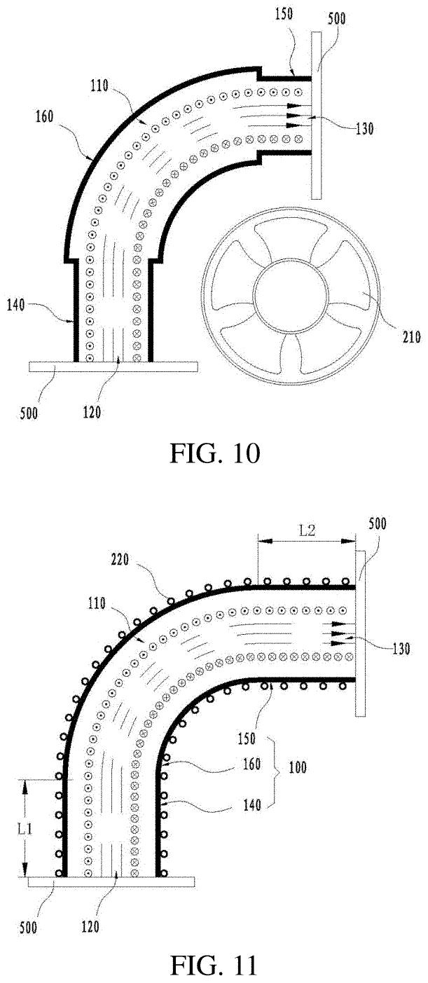

Referring to FIG. 10, as a preferred implementation of the cooling unit provided by the present embodiment, the air-cooling device 210 can be arranged outside the channel body 100 as the cooling unit. That is, the heat dissipation is conducted by speeding up the air flow.

Specifically, a fan can be used. The air outlet of the fan faces the channel body 100. The on-off and working time of the fan are adapted to the working state of the A channel 110 to ensure that the fan keeps on working during the working period of the A channel 110 to achieve the heat dissipation of the channel body 100. The size and scope of the air outlet of the fan are matched with the outer dimension and shape of the channel body 100.

Referring to FIG. 1 to FIG. 9, and FIG. 11 to FIG. 15, as another preferred implementation of the cooling unit provided by the present embodiment, the cooling unit is formed by a cooling passage provided on the channel body 100, and a cooling fluid is contained in the cooling passage. That is, the cooling passage is arranged on the channel body 100, and the fluid configured for cooling and reducing temperature is introduced into the cooling passage, so as to achieve temperature reduction. Compared with the air-cooling manner, introducing the fluid into the cooling passage for temperature reduction is conductive to increasing the heat absorbed by the cooling fluid per unit time and then improving temperature reduction efficiency, as long as the cooling passage is arranged in proper form and scope. The cooling fluid is optimally capable of circulating in order to achieve continuous temperature control. The cooling passage has a cooling fluid inlet and a cooling fluid outlet.

Further, the cooling passage is arranged on the outer side wall of the channel body 100. Compared to that arranged on the inner side wall of the channel body 100, the cooling passage arranged on the outer side wall of the channel body 100 facilitates processing, assembly, and repair, and meanwhile is convenient for temperature reduction and heat dissipation of the cooling passage itself, which prevents the heat absorbed from being conducted back to the channel body 100. Moreover, the cooling passage arranged on the inner side wall of the channel body 100 may occupy a part of the space of the A channel 110, making the space through which the plasma flows narrower. In addition, particles such as the impurity component 00b will gradually deposit in the transport channel. If the cooling passage is located on the inner side wall of the channel body 100, the particles will deposit on the cooling passage, which will increase the difficulty of cleaning. Therefore, arranging the cooling passage on the outer side wall of the channel body 100 is a more reliable option, as shown in FIG. 1 to FIG. 9, and FIG. 11 to FIG. 15.

A more specific implementation is as follows. As shown in FIG. 9, the cooling passage is formed by the interlayer 230 arranged on the channel body 100, and the cooling fluid inlet and the cooling fluid outlet are arranged on the cooling passage. In other words, the interlayer 230 having an inner wall and an outer wall is used, the inner wall is used for separating the interior of the A channel from the cooling fluid, and the outer wall is used for isolating the cooling fluid from the exterior. This arrangement maximizes the contact area between the cooling fluid and the channel body 100, thereby greatly improving cooling efficiency. However, this implementation has higher requirements for processing technique and is high in cost. As such, this implementation is the best as long as the implementation cost is acceptable.

When the interlayer 230 is used to form the cooling passage, the size of the interlayer 230 generally should be taken into consideration, which will affect the size of the channel body 100. In this regard, the width of the interlayer 230 generally will not be too large. Preferably, the width of the interlayer 230 forming the cooling passage is 1 mm-10 mm.

Another more specific implementation is as follows. Referring to FIG. 1 to FIG. 8, and FIG. 11 to FIG. 15, the cooling passage is formed by the spiral tube 220 arranged on the channel body 100, one end of the spiral tube 220 is the cooling fluid inlet, and the other end of the spiral tube 220 is the cooling fluid outlet. That is, the spiral tube 220 is sleeved on the outer side wall of the channel body 100. For this implementation, the cooling effect and processing cost need to be determined according to the contact between the tube wall of the spiral tube 220 and the outer side wall of the channel body 100. Those skilled in the art can understand that, for the spiral tube 220 of the same length, the larger the contact area between the tube wall of the spiral tube 220 and the outer side wall of the channel body 100 is, the higher the cooling efficiency is.

The spiral tube 220 can also be replaced by tubes configured in other shapes, and the spiral tube is only one preferred implementation.

Referring to FIG. 1 to FIG. 8, and FIG. 11 to FIG. 15, the specific implementations of the spiral tube 220 differ from each other according to different cross sections. The cross section of the spiral tube 220 is circular, rectangular, semicircular, or elliptical. Among them, the manufacture of the spiral tube 220 with a circular cross section is the easiest with a relatively low processing cost. However, a line contact is formed between the spiral tube with the circular cross section and the outer wall of the channel body 100, which limits the cooling effect. The spiral tube 220 with an elliptical cross section, after being arranged properly, can result in an effectively increased contact area with the channel body 100, thereby improving the cooling efficiency. The difficulty of processing, however, will be larger than that of the spiral tube 220 with the circular cross section. While for the spiral tube 220 with a rectangular or semicircular cross section, a surface contact is formed between the spiral tube and the outer surface of the channel body 100, resulting in a relatively large contact area and the optimal cooling effect among the three. The difficulty of processing, however, is the highest. In a specific implementation, a comprehensive consideration can be made according to uses' own conditions and needs.

Cooling by the manners of the spiral tube 220 and the interlayer structure are compared. The spiral tube 220 is arranged on the outer side of the channel body 100, which will make the outer surface of the channel body 100 appear uneven, affect the layout of lines and other structures, cause interference, and thereby affect the service life. While the interlayer structure cures the deficiency. The interlayer is located in the wall of the cavity of the channel body and formed by enclosing the outer side wall and the inner side wall. Therefore, the outer surface of the channel body 100 is relatively flat and smooth, which is conducive to line layout and avoiding interference with other structures.

One end of the channel body 100 is usually connected to the plasma generator 900 for exciting a target material to generate plasma, and the other end is connected to a vacuum chamber in which a workpiece to be coated is arranged. During the working process of the transport channel, if a straight tube is used as the A channel 110 to achieve the filtering function, namely, filtering out the impurity component 00b which cannot be subject to a direction adjustment controlled by the magnetic field 00d, it is likely that a large amount of impurity components 00b directly enters the vacuum chamber 1000, resulting in a decline in the coating quality. Therefore, the channel body 100 in the present embodiment is preferably formed by a bent tube or a folded tube.

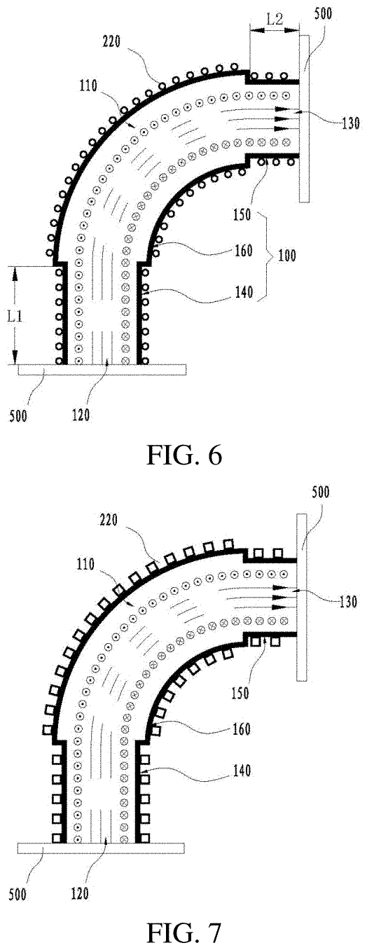

Preferably, referring to FIG. 6 to FIG. 15, the A channel 110 is a variable-diameter cavity-type channel. The larger the diameter of the cavity-type channel is, the more smooth the transport of the plasma is, which means that more particles can pass. The smaller the diameter is, the better the filtering effect is, which means more impurity components 00b that cannot be controlled by the magnetic field 00d will be trapped. Where the diameter is large or where the diameter is small can be determined according to needs in the actual implementation.

Referring to FIG. 1 to FIG. 15, since the channel body 100 is a bent tube or a folded tube, flow directions of the plasma in the A inlet 120 and the A outlet 130 are inevitably different. Preferably, an included angle between the flow directions in the A inlet 120 and the A outlet 130 is in a range of 30°-270°.

As shown in FIG. 1 to FIG. 15, the included angle between the flow directions in the A inlet 120 and the A outlet 130 is 30°, 90°, 180°, or 270°.

The A inlet 120 and the A outlet 130 usually need to be assembled with and connected to other equipment by using the flange 500 to ensure the sealing performance and stability at the connecting portion. In order to adapt to the arrangement of the flange 500, straight tubes are generally required respectively at two ends of the A channel 110 as transitions, so as to improve the sealing performance, reliability and other process performance of the connecting portion between the flange 500 and the channel body 100. In this regard, a preferred implementation of the embodiment of the present application is as follows. The channel body 100 includes the straight tubular A channel body section 140 and the straight tubular B channel body section 150 that are located at two ends, and the A channel body section 140 and the B channel body section 150 are connected by the arc-shaped C channel body section 160, as shown in FIG. 1 to FIG. 15.

In practice use, referring to FIG. 6 to FIG. 15, the cross sections of the A channel body section 140 and the B channel body section 150 may preferably have the same size. The reason for this implementation is that the plasma generator 900 can also be directly connected to the vacuum chamber 1000 when the plasma transport channel device of the present application is not used, which shows that the connection ports of the two apparatuses normally should be the same. Therefore, the cross sections of the A channel body section 140 and the B channel body section 150 can preferably have the same size. Moreover, it is convenient for uniform material selection and processing, which can reduce processing cost. The cross section of the C channel body section 160 has a different size from that of the A channel body section 140. The reason is that the requirements for filtering, transport properties and the like of the A channel 110 differ in reality, the C channel body section 160 with an appropriate cross-sectional size can be selected according to actual demands, and two ends of the C channel body section 160 are respectively assembled with the A channel body section 140 and the B channel body section 150.

Obviously, if the connection port of the plasma generator is inconsistent with the connection port of the vacuum chamber 1000, the A channel body section 140 and the B channel body section 150 can have different cross-sectional sizes.

Besides, referring to FIG. 11, the cross section of the C channel body section 160 can also have the same size as those of the A channel body section 140 and the B channel body section 150.

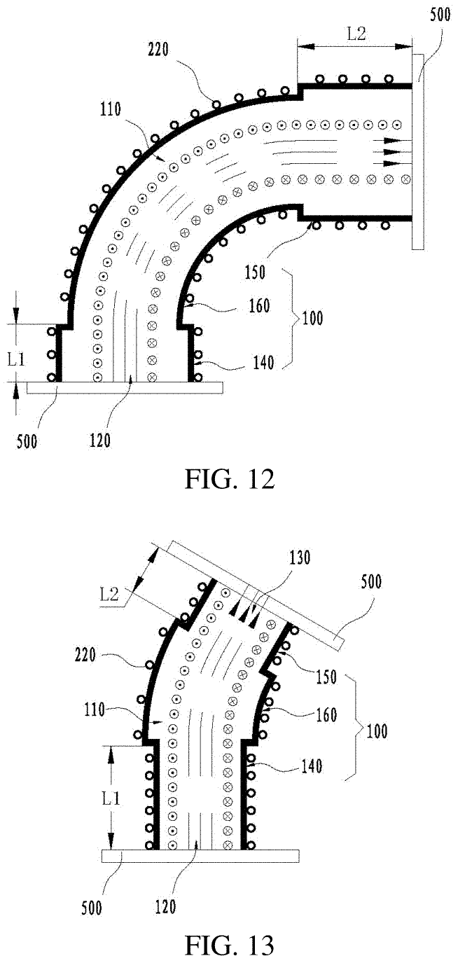

As shown in FIG. 6 to FIG. 10, and FIG. 12 to FIG. 15, in general, the positions of the C channel body section 160 relative to the connection port of the plasma generator 900 and the connection port of the vacuum chamber 1000 are different. In this regard, preferably, the lengths of the A channel body section 140 and the B channel body section 150 are different in the present embodiment.

Obviously, referring to FIG. 11, the lengths of the A channel body section 140 and the B channel body section 150 can also be identical.

Referring to FIG. 1 to FIG. 5, the embodiment of the present application further provides coating equipment, including the plasma transport channel device provided by the above embodiment. The coating equipment is one or any combination of magnetron sputtering equipment, vacuum-arc equipment, chemical vapor deposition equipment and pure ion vacuum coating equipment.

Through using the above-mentioned plasma transport channel device, the coating equipment provided by the embodiment of the present application can concurrently filter impurities in the plasma and cool the channel body 100 in the working process, so as to ensure the plasma transport channel device continuously exerts a stable filtering effect, thus beneficial to improving a coating quality.

### Embodiment 3

Referring to FIG. 1 to FIG. 15, the embodiment of the present application further provides a plasma transport channel device, including the channel body 100. The A channel 110 configured for a transport of a plasma is formed inside the channel body 100. Two ends of the A channel 110 constitute the A inlet 120 and the A outlet 130, respectively. An adsorption unit configured for adsorbing the impurity component 00b in the plasma is arranged on the inner wall of the channel body 100. The impurity component includes neutral particles and microscopic particles.

For the plasma transport channel device provided by the embodiment of the present application, the A channel 110 is formed in the channel body 100. The plasma enters from the A inlet 120 at one end of the A channel 110, and exits from the A outlet 130 at the other end of the A channel 110. The adsorption unit arranged on the inner wall of the channel body 100 realizes the adsorption of the impurity component in the plasma, thereby improving a filtering effect.

Moreover, since the adsorption unit is a functional part used to filter out the impurity component, when the impurity component accumulates to a certain amount that affects the filtering effect or the transport of the plasma, the adsorption unit can be cleaned to achieve the purpose of recovering/improving the filtering effect. If the adsorption unit is detachable, the cleaning of the adsorption unit will be more convenient. In this regard, preferably, the adsorption unit and the channel body 100 are detachably connected in the embodiment of the present application, referring to FIG. 1 to FIG. 5.

In order to further improve the filtering effect of the plasma in the A channel 110, and make the impurities in the plasma gradually decrease during the process of the plasma flowing to the A outlet 130, a preferred implementation of the embodiment of the present application is as follows. Referring to FIG. 1 to FIG. 5, the adsorption unit is arranged along the length range of the channel body 100. The adsorption unit arranged along the length range of the channel body 100 can gradually trap the impurity component 00b in the plasma during the process of the plasma flowing through the channel, so that the final outflow from the A outlet 130 are all charged ions and electrons. Moreover, it can also relieve the filtering pressure of the channel body 100, so that everywhere in the length direction of the channel body 100 can perform effectively. Since the plasma flows at a high rate, arranging the adsorption unit locally is far from meeting the filtering demand. Therefore, arranging the adsorption unit along the length range of the channel body 100 can better meet the requirement for filtering impurities of high-speed flying plasma, and improve the filtering effect.

Specifically, referring to FIG. 1 to FIG. 5, the adsorption unit is composed of plates or blocks arranged on the inner wall of the channel body 100. The area of the plate is large, and the purpose of filtering the impurity component in the plasma can be achieved by making full use of the large surface area of the plate.

Since the plasma is excited and generated by the plasma generator 900, and has high initial velocity and incompletely definite initial direction, this is especially true for neutral particles that cannot be controlled by the magnetic field 00d, the neutral particles may fly and fall on the inner wall of the channel body 100 during the process of filtering the impurity component 00b. In order to avoid this situation as much as possible, preferably in the embodiment of the present application, referring to FIG. 1 to FIG. 4, the adsorption unit is composed of annular plates 410 arranged on the inner wall of the channel body 100, the center line of each annular plate 410 is consistent with the center line of the channel body 100, and the annular plates 410 are arranged at intervals along the length direction of the channel body 100. The plate for filtration configured in an annular shape can be arranged along the circumferential direction of the inner wall of the channel body 100, which can increase the probability of the impurity component 00b falling and depositing on the inner wall of the channel body, thereby improving the adsorption performance of the transport channel to the impurity component 00b, and enabling more impurity components 00b to deposit on the inner wall of the transport channel.

If the annular plate 410 is a flat board, in order to maximize the probability of the impurity component 00b depositing on the inner wall of the channel body 100, the distance between two adjacent annular plates 410 must be smaller, or the surface of the annular plate 410 needs to be enlarged. The former will increase cost, and the latter will restrict the channel where the plasma flows, thereby affecting the transport of the plasma in the A channel 110. In this regard, a preferred implementation of the embodiment of the present application is as follows. As shown in FIG. 1 to FIG. 4, the annular plate 410 is in a trapezoid shape, and the distance between the inner ring side 411 of the annular plate 410 and the A inlet 120 is smaller than that between the outer ring side 412 and the A inlet 120. In other words, the surface of the annular plate 410 arranged close to the A inlet 120 is convex outward along the transport direction of the plasma, and the surface of the annular plate 410 arranged close to the A outlet 130 is concave inward along the transport direction of the plasma. Compared with the flat annular plate 410, on the one hand, the assembly distance between two adjacent annular plates 410 is increased while ensuring sufficiently large effective contact area between the plate and the plasma, and the amount of the plates assembled is greatly reduced, thereby saving cost; on the other hand, the inner diameter of the inner ring side of the annular plate 410 is larger, which can give way to the plasma transport to the maximum. In short, it can not only improve the filtering effect, but also minimize the impact on the plasma transport.

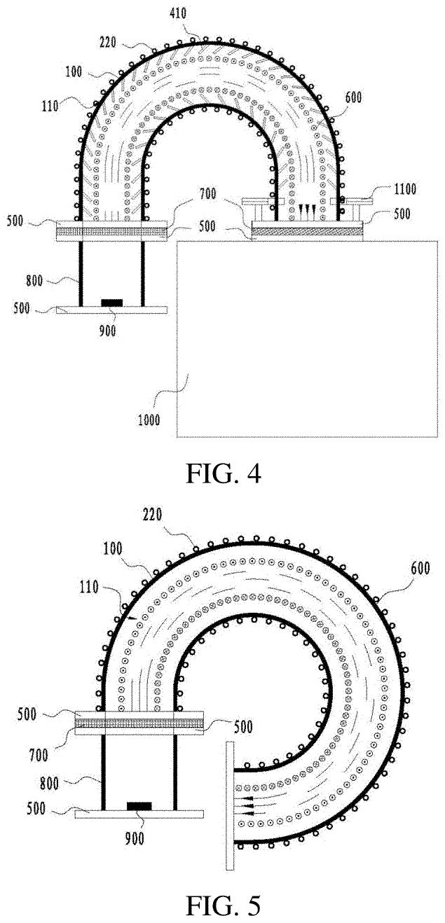

The working principle is as follows. As shown in FIG. 1, FIG. 3 and FIG. 4, the side of the cross section of the annular plate 410 and the inner wall of the channel body 100 are arranged at an included angle, that is, the outer surface of the annular plate 410 tilts toward the inner wall of the channel body 100. Further, it can be seen from the figures that the opening of the included angle faces downward, that is, the outer surface of the annular plate 410 is arranged toward the side of the plasma generator. In this way, the impurity component 00b can attack the outer surface of the annular plate 410 during the plasma transport process. If the impurity component rebounds after attacking the outer surface of the annular plate 410, the rebound occurs in the direction toward the inner wall of the channel body 100, so that the impurity component 00b can concurrently deposit on the outer surface of the annular plate 410 and the inner wall of the channel body 100, thereby increasing the amount of the impurity component 00b trapped in the transport channel, and achieving the effect of improving the adsorption performance of the channel body 100 to the impurity component 00b. In summary, by arranging the annular plate 410 in the channel body 100, more impurity components 00b can deposit in the channel body 100, thereby realizing the purpose of filtering the impurity component 00b by the channel body 100.

The included angle between the annular plate 410 and the inner wall of the channel body 100 is in a range of 15°-75°.

Referring to FIG. 1 to FIG. 15, the flanges 500 are arranged at two ends of the channel body 100. The flanges 500 are configured for realizing the connection of the channel body to the plasma generator 900 and the vacuum chamber 1000, respectively, which ensures an improvement in connection stability and sealing performance.

The magnetic field device 600 is arranged beside the channel body 100. The magnetic field device 600 includes a coil, a positive lead and a negative lead. The positive lead is connected between one end of the coil and a power supply, and the negative lead is connected between the other end of the coil and the power supply. Alternatively, the positive lead and the negative lead are respectively formed by extending two ends of the coil. The intensity of the magnetic field 00d applied by the magnetic field device 600 is 0.01 T-0.98 T, referring to FIG. 1 to FIG. 15.

Specifically, referring to FIG. 1 to FIG. 15, the magnetic field device 600 may be composed of a coil that can generate the electromagnetic field 00d after being energized. The coil is arranged along the length direction of the channel body 100, and the coil is concentric with the channel body 100. In this way, the direction along which the charged ion 00a is guided by the magnetic field 00d generated after the current 00c flows through the coil can be consistent with the direction of the channel.

The channel body 100 is made of stainless steel, oxygen-free copper, copper alloy, or aluminum alloy.

Referring to FIG. 1 to FIG. 5, the embodiment of the present application further provides coating equipment, including the above-mentioned plasma transport channel device. The coating equipment is one or any combination of magnetron sputtering equipment, vacuum-arc equipment, chemical vapor deposition equipment and pure ion vacuum coating equipment.

In the above embodiment, the A inlet 120 of the channel body 100 is connected to the anode assembly 800 through the flange 500, and the insulating plate 700 is arranged at the connecting portion between the channel body 100 and the anode assembly 800. The plasma generator 900 is arranged in the anode assembly 800, and the plasma generator 900 is used to excite a target material to generate flying plasma. The plasma includes the charged ion 00a and the impurity component 00b. The flange 500 for connecting other equipment is also arranged at the end of the anode assembly 800 close to the plasma generator 900. The A outlet 130 of the channel body 100 is connected to the vacuum chamber 1000 through the flange 500; the insulating plate 700 is arranged at the connecting portion between the channel body 100 and the vacuum chamber 1000; and the scanning device 1100 is further provided at the end of the channel body 100 close to the A outlet 130.

The plasma transport channel device provided in the above embodiment can filter out the impurity component 00b and microscopic particles, and only allows the transport of the charged ion 00a and electrons, thereby improving film performance.

If the plasma transport channel device is not included in the coating equipment, and the impurity component 00b and the microscopic particles in the plasma are not filtered, all particles, ions, and impurities in the plasma will deposit on the surface of a product to be processed, which causes problems such as the existence of a large amount of relatively large particles on film, low film adhesion, the occurrence of defects, and uncontrollable uniformity.

Specifically, during the implementation, the bias voltage of the A channel is set in a range of 0 V-30 V.

Referring to FIG. 6 to FIG. 15, the length of the A channel body section 140 is denoted as L1, and the length of the B channel body section 150 is denoted as L2. In the specific implementation, L1 is preferably not equal to L2. The reason is that unlimited settings of L1 and L2 can make equipment installation, operation, and maintenance more flexible, and is also more convenient to controlling particles on nano-film.

The advantages and disadvantages of the spiral tube 220 with various cross-sectional shapes are analyzed as follows. The spiral tube 220 with a circular cross section has the lowest cost, but the cooling effect thereof is limited. The spiral tube 220 with a rectangular or semicircular cross section has the best cooling effect, but is relatively difficult for processing and high in cost. The spiral tube 220 with an elliptical cross section has the cooling effect, processing difficulty, and cost all in a moderate level between the above two.

If the interlayer 230 having inner and outer walls is adopted, a better cooling effect will be achieved as compared to the spiral tube 220. However, the cost is higher and the processing is more difficult. If the processing cost and processing difficulty of this implementation are acceptable, it is also a more preferable way.

The plasma can be generated by a method selected from one or any combination of magnetron sputtering, vacuum arc, chemical vapor deposition and pure ion vacuum coating. Furthermore, a type of plasma source included in the vacuum coating equipment to which the above-mentioned plasma transport channel device is applicable is one or any combination of a magnetron sputtering source, a vacuum-arc source, a chemical vapor deposition source and a pure ion coating source.

The vacuum coating equipment to which the above-mentioned plasma transport channel device is applicable includes an ion beam cleaning source. The ion beam cleaning source can generate high-energy ions to bombard, clean, and etch the surface of a part to be processed in a microscopic manner, thereby resulting in higher film adhesion and lower stress during coating.

Specifically, the high-energy ions are preferably high-energy argon ions.

Referring to FIG. 1 to FIG. 5, the coating equipment can be single-chamber vacuum coating equipment with only one vacuum chamber 1000, or multi-chamber vacuum coating equipment with multiple vacuum chambers 1000. The number of the vacuum chambers 1000 is in a range of 1-50.

In the vacuum coating equipment, a sample can be transported by a method selected from one or any combination of a motor drive, a cylinder drive, and a magnetic drive.

The cross section of the channel body 100 may be U-shaped, semicircular, right-angled, or in an off-plane shape.

The diameter of the A channel 110 can be selected within the range between 10 mm and 800 mm; the lengths of the A channel body section 140 and the B channel body section 150 can be respectively selected within the range between 0 mm and 2000 mm; and the angle of the bent tube, that is, the included angle between the flow directions of the plasma in the A outlet 130 and the A inlet 120, can be selected within the range between 30° and 270°. Of course, the ranges of these parameters selected are not absolute, and those skilled in the art can also expand the range within which the parameters are selected according to actual needs.

Referring to FIG. 6 to FIG. 15, the diameters of the straight tube section and the bent tube section can be the same or different independently.

The plasma transport channel device can be processed by a method selected from one or any combination of welding, machining or a combination thereof, and any other existing processing method.

In the specific implementation, referring to FIG. 1 to FIG. 15, the cooling unit arranged on the channel body 100 may be any one or any combination of the air-cooling device 210, a water-cooling copper tube, and the water-cooling interlayer 230. Specifically, the cross section of the water-cooling copper tube can be circular, elliptical, semicircular or rectangular, and the material thereof is preferably copper alloy or pure copper.

### Embodiment 4

Referring to FIG. 1 to FIG. 19B, taking a diamond-like carbon film as an example, a comparison is made to illustrate the impact of the coating equipment with and without the plasma transport channel device on the coating quality. A target material is divided into two equal parts, one for an experimental group and the other for a control group. The experimental group uses the coating equipment with the plasma transport channel device to perform coating, and the control group uses the coating equipment without the plasma transport channel device to conduct coating operations. Identical workpieces are treated in the experimental group and the control group.

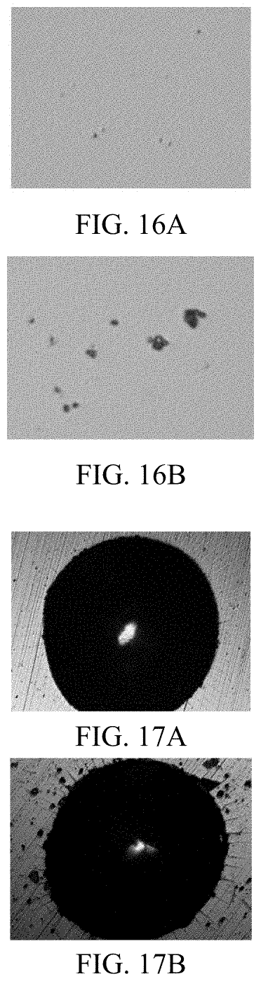

The coating is performed on the workpieces under the same control conditions, and experimental results obtained are shown in FIG. 16A to FIG. 19B.

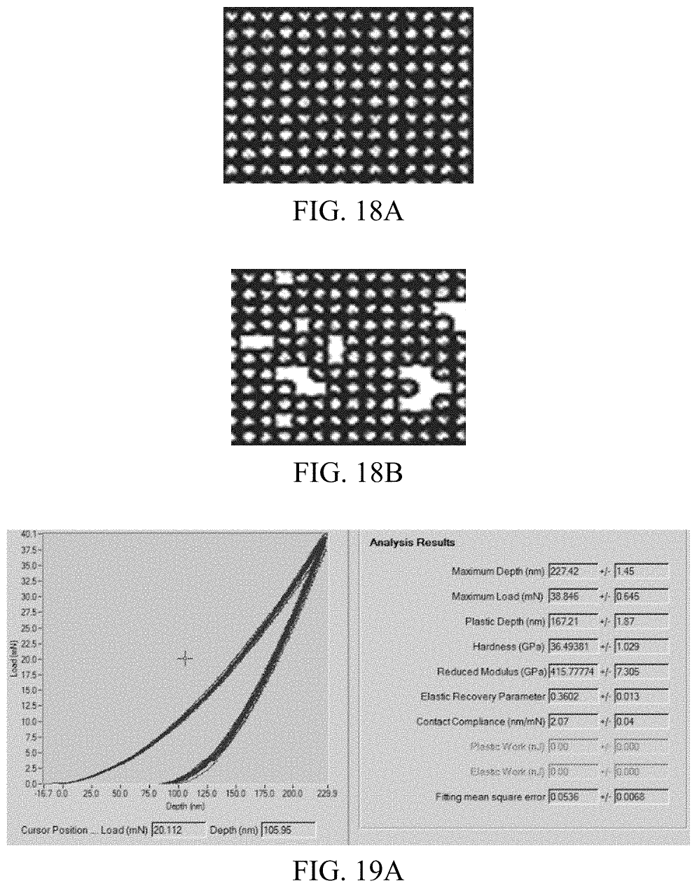

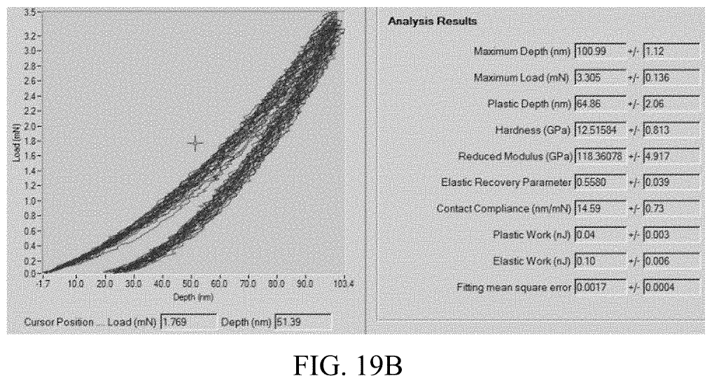

Specifically, the experimental results of the experimental group are shown in FIG. 16A, FIG. 17A, FIG. 18A, and FIG. 19A, and the experimental results of the control group are shown in FIG. 16B, FIG. 17B, FIG. 18B, and FIG. 19B. The specific comparison analysis is as follows:

(1) It can be concluded from the comparison of the results shown in FIG. 16A and FIG. 16B that the particles in the experimental group are smaller and fewer, resulting in better film performance; and more and larger particles appear in the control group, resulting in poor film performance.

(2) It can be concluded from the comparison of the results shown in FIG. 17A and FIG. 17B that the adhesion between film and substrate product of the experimental group is HF1; and the adhesion between film and substrate product of the control group is HF2-HF3.

(3) It can be concluded from the comparison of the results shown in FIG. 18A and FIG. 18B that the film of the experimental group is dense without defects; and the film of the control group is loose and defective.

(4) It can be concluded from the comparison of the results shown in FIG. 19A and FIG. 19B that the film hardness in the experimental group reaches 30 GPa-40 GPa; and the film hardness in the control group is generally less than 20 GPa. That is, the film hardness in the experimental group is significantly greater than that of the control group.

In summary, through the above comparisons, it is clear that the coating quality of the experimental group is significantly better than that of the control group. Therefore, it is very necessary to add the plasma transport channel device configured for filtering impurity particles in the coating equipment.

The above descriptions are only the preferred embodiments of the present invention. It should be pointed out that for those of ordinary skills in the art, without departing from the principle of the present invention, several improvements and modifications can be made, and these improvements and modifications should also be regarded as falling within the protection scope of the present invention. The structures, devices, and operating methods that are not specifically described and explained in the present invention, unless otherwise specified and limited, are implemented in accordance with conventional means in the art.

1. A plasma transport channel device, comprising a channel body, wherein an A channel configured for a transport of a plasma is formed inside the channel body, two ends of the A channel constitute an A inlet and an A outlet, respectively, a cooling unit configured for cooling the channel body is arranged on or beside the channel body, and/or, an adsorption unit configured for adsorbing an impurity component in the plasma is arranged on an inner wall of the channel body.

2. The plasma transport channel device according to claim 1, wherein the cooling unit is formed by an air-cooling device arranged outside the channel body.

3. The plasma transport channel device according to claim 1, wherein the cooling unit is formed by a cooling passage arranged on the channel body, and a cooling fluid is contained in the cooling passage.

4. The plasma transport channel device according to claim 3, wherein the cooling passage is arranged on an outer side wall of the channel body.

5. The plasma transport channel device according to claim 4, wherein the cooling passage is formed by an interlayer arranged on the channel body, and a cooling fluid inlet and a cooling fluid outlet are arranged on the cooling passage.

6. The plasma transport channel device according to claim 4, wherein the cooling passage is formed by a spiral tube arranged on the channel body, one end of the spiral tube is a cooling fluid inlet, and another end of the spiral tube is a cooling fluid outlet.

7. The plasma transport channel device according to claim 1, wherein the adsorption unit is arranged along a length range of the channel body.

8. The plasma transport channel device according to claim 1, wherein the adsorption unit is formed by a plate or a block arranged on the inner wall of the channel body.

9. The plasma transport channel device according to claim 1, wherein the adsorption unit is formed by annular plates arranged on the inner wall of the channel body, a center line of each of the annular plates is consistent with a center line of the channel body, and the annular plates are arranged at intervals along a length direction of the channel body.

10. The plasma transport channel device according to claim 9, wherein each of the annular plates is in a trapezoid shape, and a distance between an inner ring side of the annular plates and the A inlet is smaller than a distance between an outer ring side and the A inlet.

11. The plasma transport channel device according to claim 1, wherein a magnetic field device is arranged beside the channel body, and an intensity of a magnetic field applied by the magnetic field device is 0.01 T-0.98 T.

12. The plasma transport channel device according to claim 6, wherein a cross section of the spiral tube is circular, rectangular, elliptical, or semicircular.

13. The plasma transport channel device according to claim 1, wherein the channel body is a bent tube or a folded tube.

14. The plasma transport channel device according to claim 1, wherein the A channel is a variable-diameter cavity-type channel.

15. The plasma transport channel device according to claim 1, wherein an included angle between a flow direction in the A inlet and a flow direction in the A outlet is 30°, 90°, 180°, or 270°.

16. The plasma transport channel device according to claim 1, wherein the channel body comprises a straight tubular A channel body section and a straight tubular B channel body section located at two ends of the channel body, and the A channel body section and the B channel body section are connected by an arc-shaped C channel body section.

17. The plasma transport channel device according to claim 16, wherein a cross section of the A channel body section and a cross section of the B channel body section have the same size, and a cross section of the C channel body section and the cross section of the A channel body section have different sizes.

18. The plasma transport channel device according to claim 16, wherein a length of the A channel body section and a length of the B channel body section are different.

19. The plasma transport channel device according to claim 5, wherein a width of the interlayer forming the cooling passage is 1 mm-10 mm.

20. A coating equipment, comprising the plasma transport channel device according to claim 1, wherein the coating equipment is one or any combination of magnetron sputtering equipment, vacuum-arc equipment, chemical vapor deposition equipment and pure ion vacuum coating equipment.
